(19) United States
(12) Patent Application Publication
(10) Pub. No.: US 2014/0082916 A1
(43) Pub. Date: Mar. 27, 2014

(54) APPARATUS FOR ATTACHING SEED

(71) Applicants: Chang Hyun Son, Seoul (KR); Bum Sup Kim, Seoul (KR)

(72) Inventors: Chang Hyun Son, Seoul (KR); Bum Sup Kim, Seoul (KR)

(73) Assignee: LG INNOTEK CO., LTD., Seoul (KR)

(21) Appl. No.: 14/118,118

(22) PCT Filed: May 17, 2012
(86) PCT No.: PCT/KR2012/003886

§ 371 Date: Nov. 15, 2013

(30) Foreign Application Priority Data
May 17, 2011 (KR) 10-2011-0046515

(51) Int. Cl. C30B 23/02

(52) U.S. Cl. CPC C30B 23/02
USPC 29/428; 118/728

(57) ABSTRACT

Disclosed is an apparatus for attaching a seed. The apparatus for attaching the seed includes a holder fixing part to fix a seed holder; a pressing part to apply a pressure to the seed holder; and a seed fixing part provided under the seed holder to fix the seed.

### TECHNICAL FIELD

The disclosure relates to an apparatus for attaching a seed.

### BACKGROUND ART

In general, materials are very important factors to determine the property and the performance of final products in the electric, electronic and mechanical industrial fields.

Since silicon (Si) used as a representative semiconductor device material is weak at a temperature of 100? or more, a semiconductor device may erroneously operate or may be failed, the semiconductor device requires various cooling apparatuses. As silicon (Si) has the physical limitation, wide-bandgap semiconductor materials such as SiC, GaN, AlN, and ZnO have been spotlighted as next semiconductor device materials.

In this case, when comparing with GaN, AlN, and ZnO, SiC represents the superior thermal stability and superior oxidation-resistance property. In addition, the SiC has the superior thermal conductivity of about 4.6 W/Cm?, so the SiC can be used for fabricating a large-size substrate having a diameter of about 2 inches or above. In particular, the single crystal growth technology for the SiC is very stable actually, so the SiC has been extensively used in the industrial field as a material for a substrate.

The SiC single crystal is manufactured through a seeded growth sublimation scheme.

According to the seeded growth sublimation scheme, a raw material is received in a crucible, and a SiC single crystal serving as a seed is provided on the raw material. Temperature gradient is formed between the raw material and the seed, so that the raw material is dispersed to the seed, and re-crystallized to grow a single crystal.

In order to perform the process, a seed used to grow the single crystal is attached to an additional member such as a cover of a crucible. Since quality of the single crystal grown on the surface of the seed may be greatly affected by the attachment state of the seed, the attachment process of the seed is very important. In addition, if the surface of the seed used to grow the single crystal is fixed in the direction of gravity due to the arrangement structure of the seed, the seed may be dropped due to the weight and the attachment state of the seed.

Therefore, before the process of growing the single crystal is performed, the seed and the seed holder to which the seed is attached must be stably and firmly attached.

### DISCLOSURE OF INVENTION

### Technical Problem

The embodiment can stably attach a seed to a seed holder.

### Solution to Problem

According to the embodiment, there is provided an apparatus for attaching a seed. The apparatus for attaching the seed includes a holder fixing part to fix a seed holder; a pressing part to apply a pressure to the seed holder; and a seed fixing part provided under the seed holder to fix the seed.

### Advantageous Effects of Invention

As described above, the apparatus for attaching the seed includes a pressing part and a seed fixing part.

The pressing part can transfer the uniform pressure to the seed holder and the seed. The adhesive strength between the seed holder and the seed can be improved due to the high compressive strength of the pressing part. In addition, the seed can be stably and firmly attached to the seed holder by removing the bubbles between the seed and the seed holder. Therefore, when growing a single crystal, the seed can be prevented from being delaminated from the seed holder. Therefore, when the single crystal is grown, the product yield of the single crystal can be improved.

The seed fixing part is provided under the seed, thereby preventing the seed from being contaminated. In other words, an adhesive material is coated on the seed, and the pressing part provided on the seed holder attaches the seed to the seed holder by applying the pressure to the seed holder. In this case, a small amount of the adhesive material leaks from the interfacial surface between the seed holder and the seed. According to the present embodiment, the seed fixing part is provided under the seed, so that the leaking adhesive material can be prevented from being introduced into the surface of the seed. Therefore, the impurities of the single crystal grown from the seed can be minimized. Therefore, the high-quality single crystal can be grown.

In addition, the seed fixing part includes at least one pore, and the intervals between pores may correspond to each other. Since the pores have the intervals corresponding to each other, the uniform temperature can be applied to the seed, and uniform cooling can be achieved during the cooling procedure. Therefore, the seed can be prevented from being cracked due to the thermal shock.

### BRIEF DESCRIPTION OF DRAWINGS

FIG. 1 is an exploded perspective view showing an apparatus for attaching a seed according to a first embodiment;

FIG. 2 is a perspective view showing the apparatus for attaching the seed according to the first embodiment;

FIG. 3 is a sectional view taken along line A-A′ of FIG. 2;

FIG. 4 is a sectional view showing a seed holder manufactured by the apparatus for attaching the seed according to the embodiment and a seed; and

FIG. 5 is a sectional view showing the apparatus for attaching the seed according to the second embodiment.

### MODE FOR THE INVENTION

In the description of embodiments, it will be understood that when a layer (or film), region, pattern or structure is referred to as being ‘on’ or ‘under’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings.

In the drawings, the dimensions and size of each layer (or film), region, pattern or structure may be exaggerated, omitted, or schematically illustrated for convenience in description and clarity.

Hereinafter, exemplary embodiments will be described in detail with reference to the accompanying drawings.

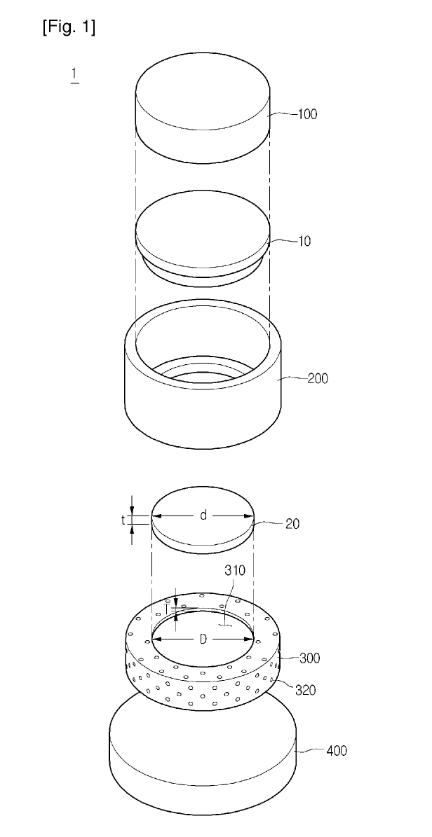

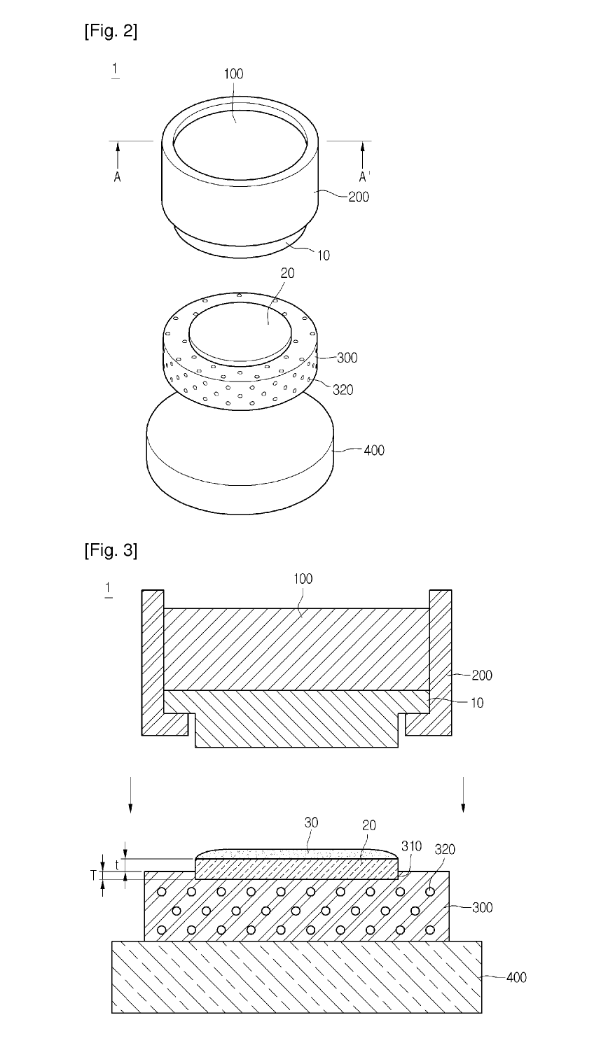

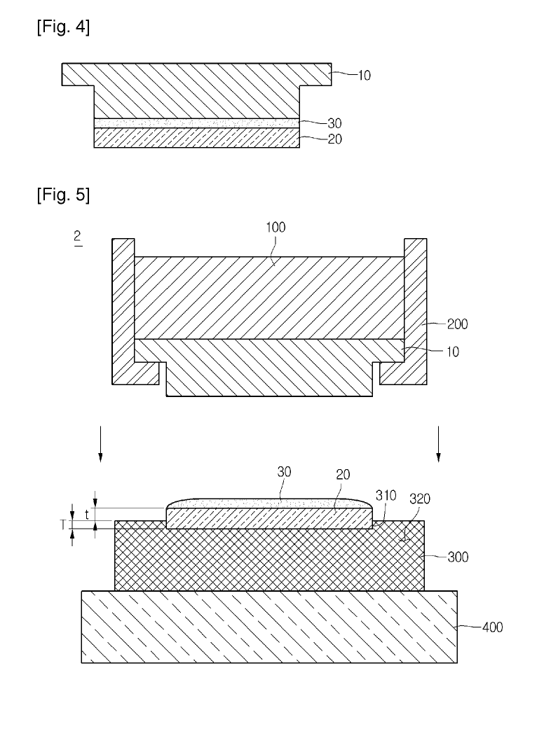

Hereinafter, an apparatus for attaching a seed according to a first embodiment will be described in detail. FIG. 1 is an exploded perspective view showing an apparatus for attaching a seed according to the embodiment, FIG. 2 is a perspective view showing the apparatus for attaching the seed according to the embodiment, and FIG. 3 is a sectional view taken along line A-A′ of FIG. 2. FIG. 4 is a sectional view showing a seed holder manufactured by the apparatus for attaching the seed according to the embodiment and a seed.

Referring to FIGS. 1 to 4, an apparatus 1 for attaching a seed according to the present embodiment includes a pressing part 100, a holder fixing part 200, a seed fixing part 300, and a heating part 400.

The pressing part 100 may be positioned on a seed holder 10.

In this case, the seed holder 10 is a device to fix a seed 20 used to grow a single crystal. The seed holder 10 may be received in a single crystal growing device in the state that the seed 20 is fixed to the seed holder 10. The seed holder 10 may include high-concentration graphite.

The pressing part 100 applies a pressure to the seed holder 10 and the seed 20 so that the seed 20 is attached to the seed holder 10. In other words, the pressing part 100 may apply a pressure to the whole upper area of the seed holder 10.

Accordingly, the pressing part 100 can transfer the uniform pressure to the seed holder 10 and the seed 20. The adhesive strength between the seed holder 10 and the seed 20 can be improved due to the high compressive strength of the pressing part 100. In addition, the seed 20 can be stably and firmly attached to the seed holder 10 by removing the bubbles between the seed holder 10 and the seed 20. Accordingly, when a single crystal is grown, the seed 20 can be prevented from being delaminated from the seed holder 10. Therefore, the product yield in the growing of the single crystal can be improved.

The pressing part 100 may include stainless steel. However, the embodiment is not limited thereto. The pressing part 100 may include various materials sufficient to apply a pressure to the seed holder 10.

Thereafter, the holder fixing part 200 may receive the pressing part 100 and the seed holder 10. Therefore, the holder fixing part 200 may have a predetermined depth.

The holder fixing part 200 may fix the seed holder 10. Accordingly, the holder fixing part 200 may include a locking part so that the seed holder 10 may be locked with the holder fixing part 200.

The holder fixing part 200 can prevent the seed holder 10 and the seed 20 from being out of the places thereof when the seed 20 is attached to the seed holder 10. In other words, the holder fixing part 20 fixes the position of the seed holder 10 so that the seed holder 10 corresponds to the seed 20.

The holder fixing part 200 may include stainless steel. However, the embodiment is not limited thereto. The holder fixing part 200 may include various materials sufficient to apply the pressure to the seed holder 10.

Thereafter, the seed fixing part 300 is provided under the holder fixing part 200. In other words, the seed fixing part 300 is provided under the seed holder 10.

The seed fixing part 300 may include a groove 310 to seat the seed 20 therein. Accordingly, the seed fixing part 300 can fix the seed 20 thereto by seating the seed 20 therein. In particular, the surface of the seed 20 for the growth of a single crystal may be seated in the groove 310 of the seed fixing part 300. Therefore, the surface of the seed 20 for the growth of the single crystal can be prevented from being contaminated.

A depth T of the groove 310 may be smaller than a thickness t of the seed 20. Accordingly, when the seed 20 is seated in the seed fixing part 300, the seed 20 may protrude from the seed fixing part 300. In other words, the top surface of the seed 20 may protrude from the seed fixing part 300. Accordingly, the seed 20 may be easily attached to the seed holder 10. In addition, after the seed 20 has been attached to the seed holder 10, the seed 20 may be easily detached from the seed fixing part 300.

The diameter D of the groove 310 may correspond to the diameter d of the seed 20. Accordingly, when attaching the seed 20 to the seed holder 10, the seed 20 may be stably fixed to the seed holder 10.

The diameter D of the groove 310 may be varied suitably for the diameter d of the seed 20.

The seed fixing part 300 is provided under the seed 20, so that the seed 20 can be prevented from being contaminated. In other words, an adhesive material 30 is coated on the seed 20, and the pressing part 100 provided on the seed holder 10 attaches the seed 20 to the seed holder 10 by applying the pressure to the seed holder 10. In this case, a small amount of the adhesive material 30 may leak from the interfacial surface between the seed holder 10 and the seed 20. According to the present embodiment, the seed fixing part 300 is provided under the seed 20, so that the leaking adhesive material 30 can be prevented from being introduced into the surface of the seed 20. Therefore, the impurities of the single crystal grown from the seed 20 can be minimized. Therefore, the high-quality single crystal can be grown.

The seed fixing part 300 is provided therein with pores 320. After the seed 20 has been attached to the seed holder 10, heat is dissipated through the pores 320 so that the seed fixing part 300 may be cooled.

Thereafter, at least one pore 320 is provided, and the intervals between the pores 320 may correspond to each other. Since the intervals between the pores 320 correspond to each other, the uniform temperature can be applied to the seed 20. During a cooling procedure, uniform cooling can be achieved. Therefore, the seed 20 may be prevented from being cracked due to the thermal shock.

The size of pore 320 may be in the range of 100 um to 1 mm. If the size of the pore 320 is less than 100 um, cooling may not be sufficiently achieved after the seed 20 has been attached to the seed holder 10. In addition, if the size of the pore 320 exceeds 1 mm, the pores 320 may not endure the pressure applied to the top when the seed holder 10 is attached. In other words, the seed fixing part 300 may not support the seed 20 due to the pores 320.

The seed fixing part 300 may include graphite. Since the graphite represents high thermal conductivity, the graphite can effectively transfer heat to the seed 20 when the seed 20 is attached to the seed holder 10. In addition, the uniform temperature can be transferred to the seed 20.

The heating part 400 may be provided under the seed fixing part 300. The heating part 400 melts the adhesive material 30 to attach the seed 20 to the seed holder 10. Accordingly, when the seed 20 is attached to the seed holder 10, the heating part 400 may apply heat to the seed fixing part 300. For example, the heating part 400 may include a hot plate.

Hereinafter, a method for attaching the seed 20 by the apparatus 1 for attaching the seed 20 will be described.

The seed holder 10 is received into the holder fixing part 200. The seed 20 is seated in the seed fixing part 300. The adhesive material 30 is coated on the surface of the seed 20, and the seed holder 10 and the seed 20 are provided corresponding to each other. The pressing part 100 is provided on the seed holder 10 to apply the pressure to the seed holder 10 and the seed 20. After the seed 20 has been attached to the seed holder 10, the heating part 400 is driven to carbonize the adhesive material 30 of the interfacial surface between the seed holder 10 and the seed 20. Thereafter, the driving of the heating part 400 is stopped, and the cooling procedure may be performed for three hours in the state that the load is applied to the seed holder 10 and the seed 20 by the pressing part 100. After the cooling procedure has been finished, the holder fixing part 200 may be separated from the pressing part 100. Thereafter, the seed 20 and the seed holder 10 attached to each other may be separated from the seed fixing part 300. The seed 20 and the seed holder 10 attached to each other are received in a crucible for the growth of a single crystal so that the single crystal can be grown.

Hereinafter, an apparatus for attaching a seed according to a second embodiment will be described. For the clear and brief description, the structure and the components similar to or identical to those of the first embodiment will not be further described.

FIG. 5 is a sectional view showing an apparatus 2 for attaching a seed according to the second embodiment.

Referring to FIG. 5, materials constituting the seed fixing part 300 may be provided in a mesh structure.

Therefore, the pores 320 may be provided due to the mesh structure. In addition, the pores 320 may be uniformly positioned due the mesh structure. Accordingly, the uniform temperature may be applied to the seed 20, and uniform cooling can be achieved during the cooling procedure.

Features, structures, and effects described in the above embodiments are incorporated into at least one embodiment of the present disclosure, but are not limited to only one embodiment. Moreover, features, structures, and effects exemplified in one embodiment can easily be combined and modified for another embodiment by those skilled in the art. Therefore, these combinations and modifications should be construed as falling within the scope of the present disclosure.

Although embodiments have been described with reference to illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims.

1. An apparatus for attaching a seed, the apparatus comprising:
a holder fixing part to fix a seed holder;
a pressing part to apply a pressure to the seed holder; and
a seed fixing part provided under the seed holder to fix the seed.

2. The apparatus of claim 1, wherein the seed fixing part includes a pore.

3. The apparatus of claim 2, wherein at least one pore is provided, and intervals between pores correspond to each other.

4. The apparatus of claim 3, wherein the pore has a size in a range of 100 um to 1 mm.

5. The apparatus of claim 1, wherein the seed fixing part includes graphite.

6. The apparatus of claim 5, wherein the graphite has a form of a mesh.

7. The apparatus of claim 1, wherein the seed fixing part is provided therein with a groove to seat the seed.

8. The apparatus of claim 7, wherein the groove has a depth smaller than a thickness of the seed.

9. The apparatus of claim 8, wherein the groove has a diameter corresponding to a diameter of the seed.

10. The apparatus of claim 1, further comprising a heating part under the seed fixing part.

11. The apparatus of claim 1, wherein the holder fixing part includes a locking part to lock the seed holder.

12. The apparatus of claim 1, wherein the pressing part is provided on the seed holder.

13. A method for attaching a seed, the method comprising:
placing a seed holder in a holder fixing part;
fixing a seed to a seed fixing part provided under the holder fixing part; and
attaching the seed and the seed holder.

14. The method of claim 13, wherein, in the attaching of the seed and the seed holder, the holder, the holder fixing part moves downward.

15. The method of claim 13, wherein, in the attaching of the seed and the seed holder, heat is applied to the seed fixing part.

16. The method of claim 13, wherein, in the attaching of the seed and the seed holder, a pressure is applied to the seed holder and the seed.

17. The method of claim 13, wherein the seed fixing part is provided therein with a pore.
